(19) United States
(12) Patent Application Publication
(10) Pub. No.: US 2018/0336841 A1
(43) Pub. Date: Nov. 22, 2018

(54) A SMART DRIVE DEVICE

(71) Applicant: SMARTRON INDIA PRIVATE LIMITED, Hyderabad (IN)

(72) Inventors: ROHIT KUMAR RATHI, Hanumangarh (IN); ANIL KONGOVI, Bangalore (IN)

(21) Appl. No.: 15/529,856

(22) PCT Filed: Nov. 27, 2015
(86) PCT No.: PCT/IN2015/000438

§ 371 Date: May 25, 2017

(30) Foreign Application Priority Data
Nov. 28, 2014 (IN) 4199/CHE/2014
Sep. 3, 2015 (IN) 4658/CHE/2015
Sep. 4, 2015 (IN) 4681/CHE/2015

(51) Int. Cl. G09G 3/34; H01L 33/00

(52) U.S. Cl. CPC G09G 3/34; H01L 33/00

(57) ABSTRACT

A smart drive device has been disclosed. The drive device is communicably coupled to at least one display device either in a wired manner or wireless manner. The drive device communicates with the display device and monitors the actions/activities of the display device. Further, the drive device determines the context of operation of the display device. Subsequently, the drive device selectively modifies the behavior of the display device, including the operating system executed on the display device, and the user profiles loaded onto the display device, inter-alia, based on the context of use of the display device.

### CROSS-REFERENCE TO RELATED APPLICATIONS

The application is a National Phase application filed with respect to the PCT Application No. PCT/IN2015/000438 filed on Nov. 27, 2015 with the title “A SMART DRIVE DEVICE”, The application further claims the priority of the Indian Provisional Patent Applications with No. 4199/CHE/2014 filed on filed on Aug. 28, 2014, subsequently post dated by 3 months to Nov. 28, 2014 with the title “HAND HELD SMART DRIVE SYSTEM FOR MULTIPLE COMPUTING DEVICES AND DISPLAYS”, Further, this application claims the priority of Indian Provisional Patent Application with serial No. 4658/CHE/2015 filed on Sep. 3, 2015, with the title, “A SYSTEM AND METHOD FOR DYNAMICALLY SWITCHING OR CONTEXT PERSISTENT SWITCHING BETWEEN PROXIMITY DISPLAYS/DONGLES”, and Indian Provisional Patent Application with serial No. 4681/CHE/2015 filed on Sep. 4, 2015, with the title, “A SYSTEM AND METHOD FOR RENDERING MULTIPLE DISPLAYS/DONGLES BASED ON CONTEXT OR PERSONA OF A DRIVE”. The contents of all the above mentioned application incorporated in its entirety as reference herein.

### BACKGROUND

### Technical Field

The present disclosure relates to drive devices capable of interfacing with a plurality of display devices.

### Description of Related Art

With increasing innovation in the field of cloud computing and wired/wireless data-transfer technology, the handheld mobile computing devices are integrated, at least in terms of functionalities and operations, with computing devices of different types, for example a laptop computer or a desktop computer. However, levels of integration prevalent in hardware integration are comparatively lower than the levels of integration prevalent at the (software) application level. To access the same data across multiple platforms and having the same data rendered in different devices, each of the computing devices should have individual processing and input-output units. The prevention of data-duplication achieved through cloud computing does not prevent the duplication of hardware, in case if the same data is intended to shared across multiple computing platforms.

Hence, there was felt a need for developing a smart drive capable of being used with a plurality of computing systems. Further, there was felt a need for developing a drive device capable of interfacing with a plurality of computing devices of different forms. Yet there was felt a need to prevent duplication of hardware while interfacing a plurality of computing devices.

### OBJECTS

An object of the present disclosure is to provide a drive device capable of managing the functionalities of a plurality of display devices.

Yet another object of the present disclosure is to provide a drive device capable of managing the online/offline behavior of a plurality of display devices.

Still a further object of the present disclosure is to provide a handheld drive device for controlling the functionalities of a plurality of display devices.

One more object of the present disclosure is to provide a context aware and context sensitive drive device.

Yet another object of the present disclosure is to provide a drive device that selectively alters the functionalities of a plurality of display devices, based on the context of use thereof.

Still a further object of the present disclosure is to provide a drive device that continuously monitors a plurality of display devices for learning the context of use thereof.

These and other objects and advantages envisaged by the present disclosure will become apparent from the following detailed description read in conjunction with the accompanying drawings.

### SUMMARY

The present disclosure envisages a smart computing drive device. The drive device is communicably coupled to a plurality of display devices. The smart computing drive device identifies at least the context of use of each of the display devices, and selectively modifies the behavior of the display devices, based on the identified context (of use).

In accordance with the present disclosure, the smart drive device includes a repository configured to store information related to profiles of the user. The repository is further configured to store information corresponding to operating systems previously executed by the user. The repository also stores instances of operating system previously executed by the user, information corresponding to the access rights assigned to each of the profiles of the user, information corresponding to the authentication mechanism previously used by the user to authenticate himself.

In accordance with the present discourse, the drive device further includes a processor configured to determine current location and hardware characteristics of the display device. The processor further determines current time of the day and subsequently analyzes the information stored in the repository to determine at least the profile, instance of operating system, access rights and authentication mechanism corresponding to the context of use of the display device.

In accordance with the present disclosure, the drive device is configured to modify the behavior of display device by loading onto the display device the instance of operating system relevant to the location and time of the day of the display device. The drive device further modifies the behavior of display device by loading onto the display device the profile relevant to the location and time of the day of the display device.

### BRIEF DESCRIPTION OF THE ACCOMPANYING DRAWINGS

The other objects, features and advantages will be apparent to those skilled in the art from the following description of the preferred embodiment and the accompanying drawings in which:

FIG. 1 is a block diagram illustrating the components of the smart drive device, in accordance with the present disclosure;

FIG. 1A is a block diagram illustrating a smart drive device communicably coupled with a plurality of display devices;

FIG. 1B is a block diagram illustrating a smart drive device communicably coupled with a plurality of display devices and dongles; and

FIG. 2 and FIG. 2A in combination depict a flowchart that illustrates the steps involved in a method for analyzing a context of use of a plurality of display devices coupled to a drive device, in accordance with the present disclosure.

Although the specific features of the present invention are shown in some drawings and not in others, this is done for convenience only as each feature may be combined with any or all of the other features in accordance with the present disclosure.

### DETAILED DESCRIPTION

In the following detailed description, a reference is made to the accompanying drawings that form a part hereof, and in which the various embodiments that may be practiced are shown by the way of illustration. The embodiments are described in sufficient detail to enable those skilled in the art to practice the embodiments and it is to be understood that other changes could be made to these embodiments without departing from the scope of the present disclosure. The following detailed description is therefore not to be construed in a limiting sense.

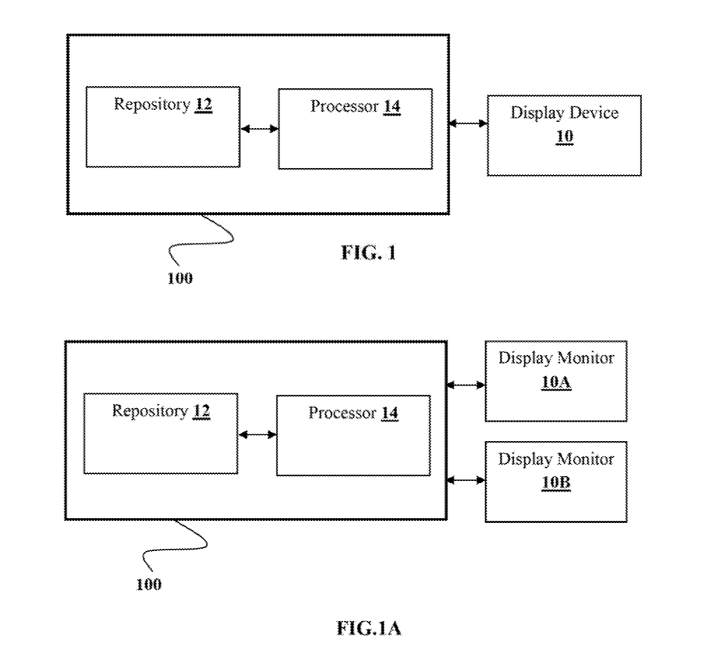

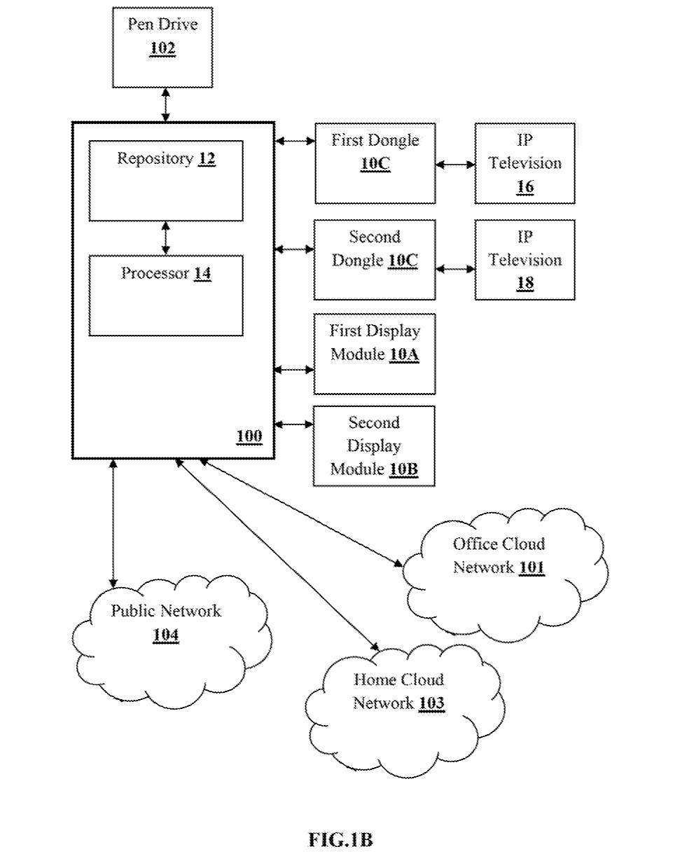

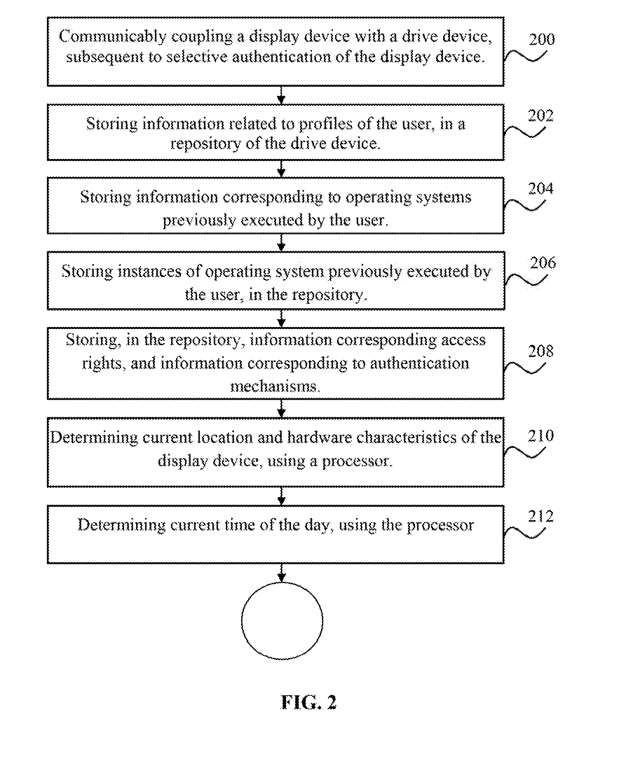

The present disclosure envisages a portable drive device. The drive device envisaged by the present disclosure provides for collaboration and interoperability between display devices communicably coupled to the drive device. Referring to FIG. 1, there is shown a block diagram illustrating the hardware components of a drive device 100.

The drive device 100, in accordance with the present disclosure is communicably coupled to at least one display device 10. The drive device 100 is communicably coupled to the display device 10 either through a wired connection or a wireless connection. Preferably, the drive device 100 communicates with the display device 10 using at least one of the communication protocols selected from the group consisting of Wi-Fi, Bluetooth, Near Field Communication (NFC), Infrared (IR), and High Definition Multimedia Interface (HDMI). The drive device 100 monitors the display device 10 communicably coupled thereto.

In accordance with the present disclosure, the data/information to be displayed on the display device 10 is stored in a repository 12 of the drive device 100. In accordance with the present disclosure, the repository 12 is configured to store at least information related to profiles of the user, information corresponding to operating systems previously executed by the user, instances of operating systems previously executed by the user, information corresponding to the access rights assigned to each of the profiles of the user, user data, media files and information corresponding to the authentication mechanism previously used by the user to authenticate himself.

The data stored in the repository 12 is typically transferred onto the drive device 100 form a plurality of sources including but not restricted to internet enabled mobile phones/smart phones, tablet devices, desktop computers, and internet enabled televisions, which communicate with the drive device 100 either in a wired manner or in a wireless manner. Further, the drive device 100 is also capable of receiving data/information (to be display on a corresponding display device 10) via well known communication protocols, including but not restricted to Bluetooth, Infrared, Wi-Fi. Alternatively, the drive device 100 can also receive data/information for display via USB or a magnetic connector.

The driver device 100 communicates with the display device 10 and receives therefrom an EDID (Extended Display Identification Data) which is a data structure that enables display device 10 to describe its display capabilities to the drive device 100. Further, a JSON (JavaScript Object Notation) file which provides information about the hardware capabilities (of display device 10) is transmitted from the display device 10 to the drive device 100. By the way of receiving the EDID and JSON file received from the display device 10, the drive device 100 interprets the hardware capabilities and the operational context of the display device 10.

In accordance with the present disclosure, the drive device includes a processor denoted by reference numeral 14. The processor 14 is configured to determine the location of the drive device 100. The information regarding the location of the drive device 100 is preferably in the form of GPS coordinates. Subsequently, depending upon the GPS coordinates, the processor 14 determines the current location of the display device 10. Further, the processor 14 elicits information corresponding to the current time. Subsequently, the processor 14 communicates with the display device 10 and elicits the hardware characteristics of the display device 10.

For example, the processor 14 determines the size of the display device 10. Subsequently, the processor 14 elicits the authentication information provided by the user while accessing the display device 10. Further, the processor 14 also elicits from the repository 12 (of the drive device 100), the stored user profiles. For example, the user profiles may include a personal profile, office profile and a guest profile. Further, the processor 14 elicits form the repository 12, information corresponding to instances of operating systems associated with the user.

Subsequently, the processor 14 analyzes the coordinates corresponding to the location of the drive device 100. For example, the processor 14 determines, based on the GPS co-ordinates, whether the drive device 100 is located at a residential address or an official address. Subsequently the processor 14 determines whether the determined coordinates have been pre-associated with any particular user profile stored in the repository 12 (of the drive device 100), and selectively loads the pre-associated profile onto the display device 10.

As explained above, the processor 14 also determines the time of the day. Subsequently, the processor 14 also identifies the access points (APs) in proximity to the drive device 100. For example, if the processor 14 identifies a virtual private network or an access point located at a location specified by the user (of the end-user device) as office location, and if the time of the day is identified as between 9:00 HRS and 6:00 HRS, then the processor 14 loads onto the display device 10, the office profile pertaining to the user.

In accordance with the present disclosure, the processor 14 further analyzes the log-in credentials provided by a user. For example, if the processor 14 determines that the user has used his official email-id (official email-id identified by the corresponding user profile available with the drive device 100), the processor 14 loads the official profile (official user account) of the user, onto the display device 10. Likewise, if the user has used his personal email-id (personal email-ids identified by the corresponding user profile available with the drive device 100), the processor 14 loads the user's personal profile onto the display device 10.

In accordance with the present disclosure, the processor 14 further analyzes the hardware characteristics of the display device 10. For example, if the size of the display device 10 is determined to be less than or equal to 5 inches, the processor 14 boots the mobile android operating system on the said display device 10 automatically. Similarly, if the size of the display device 10 is determined to be greater than 5 inches and less than or equal to 14 inches, the processor 14 boots the Windows Home operating system on the said display device 10 automatically. Similarly, if the size of the display device 10 is determined to be greater than 14 inches and less than or equal to 22 inches, the processor 14 boots Linux operating system on the said display device 10 automatically.

In accordance with the present disclosure, the drive device 100 includes at least one proximity sensor and at least one motion sensor, to determine the proximity between the drive device 100 and display device 10. Further, the Wi-Fi signal strength can also be used as a metric to determine the positioning of the drive device 100 with reference to the display device 10. The drive device 100 is further configured to determine the mode of communication used by a user to communicate with the display device 10. For example, if the user is providing gesture based inputs via a touch screen, the processor 14 identifies the display device 10 to be a mobile phone/tablet, and subsequently uploads user's personal profile. Similarly, if the user is communicating with the display device 10 via a remote-controller, the processor 14 identifies the display device 10 to be a television and subsequently loads the personal profile of the user, on to the display device 10.

In accordance with the present disclosure, the drive device 100 always boots the display device 10 with the last used Operating System and last used user profile. And in the event that a display device 10 (for example, an IP Television) has been reset to ‘factory settings’ by a user, the drive device 100 always boots the display device 10 with the default operating system and default user profile.

In accordance with the present disclosure, the drive device 100 is configured to communicate with a plurality of display devices (for example, display Monitors 10A and 10B, as shown in FIG. 1A). The drive device 100, in accordance with the present disclosure automatically detects display devices situated within a predetermined distance therefrom, and subsequently initiates a connection with detected display devices by the way of pairing. In accordance with the present disclosure, the drive device 100 stores in the repository 12, the information corresponding to all the display devices detected to be proximate to the drive device 100.

In accordance with the present disclosure, the drive device 100 detects the display devices in proximity thereto, preferably by using a uniquely coded Service Set Identifier (SSID), or by using a HDMI upstream/downstream/repeater bit, or by using the MAC (Media Access Control) address (assigned to the display devices). Further, the drive device 100 automatically searches for identifying display devices situated in proximity thereto, at predetermined time intervals. Alternatively, a user accessing the drive device 100 through a user interface (not shown in figures) communicably coupled thereto, could also trigger a search for display devices located in proximity to the drive device 100.

In accordance with the present disclosure, the drive device 100, via the user interface (preferably a display monitor) display to the user, a list of detected display devices, which are determined to be in proximity to the drive device 100. Further, the drive device 100 enables the user to select any display device from the list. Subsequently, the drive device 100 transfers at least the contextual information relevant to the user and the corresponding user profile, operating system and user data, which are identified by the processor 14 of the drive device 100 based on the context, on to the display device selected by the user, without losing the context.

Referring to FIG. 1C, the drive device 100 is communicably coupled to a plurality of display devices using at least one of the communication protocols selected from the group consisting of Wi-Fi, Bluetooth, Near Field Communication (NFC), Infrared (IR), and High Definition Multimedia Interface (HDMI). For example, the drive device 100 is connected to a first display module 10A and a second display 10B module using Wi-Gig and Mobile High-Definition Link (MHL) protocols respectively. Further, the drive device 100 is communicably coupled to a first dongle 10C and a second dongle 10D via Bluetooth and Wi-Fi protocols respectively. The first dongle 10C and the second dongle 10D are connected to respective IP televisions 16 and 18.

The drive device 100 communicates with the first display module 10A and second display module 10B, and first dongle 10C and second dongle 10D, preferably via well known multicast/broadcast/unicast protocols.

Further, the drive device 100 is also connected to a plurality of content sources including an office cloud network 101, a pen-drive 102, a home cloud network 103, and a public network 104. The drive device 100 accesses content from the aforementioned content sources.

In accordance with the present disclosure, when the user generates a request via the first display module 10A to view the documents related to his office persona, the drive device 100 retrieves relevant documents from the office cloud network 101 and delivers the documents to the first display module 10A. The drive device 100 also saves any modifications to the retrieved contents, on the office cloud network 101.

Subsequently, when the user generates a request via the second display module 10B to view the contents of the pen-drive 102, the drive device 100 accesses the pen-drive 102 and retrieves the requested content from the pen-drive 102, and transfers the content to the second display module 10B. Subsequently, when the user generates a request via the first display module 10A to view the documents related to his home persona, the drive device 100 retrieves relevant documents from the home cloud network 103 and delivers the documents to the first display module 10A. The drive device 100 also saves any modifications to the contents, on the home cloud network 103.

In accordance with the present disclosure, the drive device 100 establishes a broadcast/multicast/unicast session with each of the display modules. After establishing the session, the drive device 100 delivers the content desired by the user, to the display module/dongle desired by the user, based on the user context. For example, the drive device 100 provides for the office persona of the user to be accessed via the first display module 10A. Simultaneously, the drive device 100 provides for the home persona of the user to be accessed via the second display module 10B. Simultaneously, the first dongle 10C which is connected to the IP Television 16, accesses the contents of a pen-drive 102 communicably coupled to the drive device 100, while a second dongle 10D cooperating with the IP Television 18 accesses the home persona of the user by the way of communicating with the drive device 100.

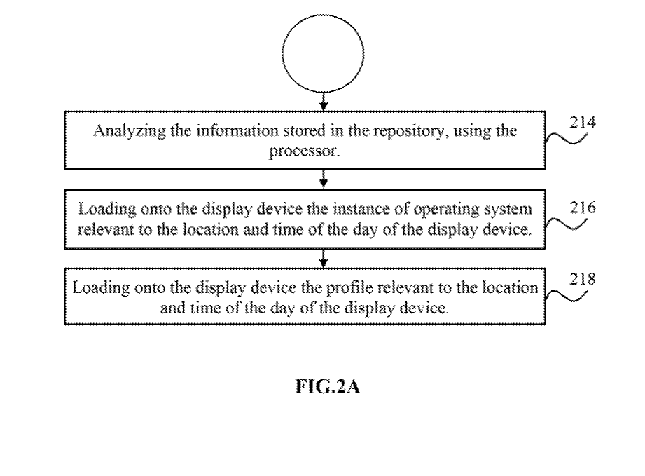

Referring to FIG. 2 and FIG. 2A in combination, there is shown a flow chart illustrating the steps involved in a method for analyzing a context of use of a plurality of display devices. The method, in accordance with the present disclosure includes the following steps:
communicably coupling a display device with a drive device (200);
storing information related to profiles of the user, in a repository of the drive device (202);
storing information corresponding to operating systems previously executed by the user (204);
storing instances of operating system previously executed by the user, in the repository (206);
storing, in the repository, information corresponding to the access rights assigned to each of the profiles of the user, and storing information corresponding to the authentication mechanism previously used by the user to authenticate himself (208);
determining current location and hardware characteristics of the display device, using a processor (210);
determining current time of the day, using the processor (212);
analyzing the information stored in the repository, using the processor and determining at least the profile, instance of operating system, access rights and authentication mechanism corresponding to the context of use of the display device (214);
modifying the behavior of display device by loading onto the display device the instance of operating system relevant to the location and time of the day of the display device (216); and
modifying the behavior of display device, by loading onto the display device the profile relevant to the location and time of the day of the display device (218).

In accordance with the present disclosure, the step of modifying the behavior of display device further includes the step of modifying the behavior of the display device by loading onto the display device the instance of operating system relevant to the authentication mechanism utilized by the user.

In accordance with the present disclosure, the step of modifying the behavior of display device further includes the step of modifying the behavior of display device, by loading onto the display device the profile relevant to the authentication mechanism utilized by the user.

In accordance with the present disclosure, the step of modifying the behavior of display device further includes the step of modifying the behavior of display device, by loading onto the display device, the profile and instance of operating system relevant to the authentication mechanism utilized by the user.

In accordance with the present disclosure, the step of modifying the behavior of display device further includes the step of modifying the behavior of display device, the profile and instance of operating system based on the network access point connected to the display device.

### TECHNICAL ADVANTAGES

The technical advantages envisaged by the present disclosure include the realization of a context sensitive drive device. The drive device envisaged by the present disclosure is capable of managing the functionalities of a plurality of display devices connected thereto. The drive device manages the online/offline behavior of a plurality of display devices, including the user profile loaded therein and the instance of operating system loaded therein. Before altering the online/offline behavior of display devices, the drive device takes into consideration the context of user. The drive device continuously monitors a plurality of display devices for learning the context of use thereof.

What is claimed is:

1. A drive device accessible to a user, said drive device configured to be communicably coupled to at least one display device, said drive device configured to selectively modify the behavior of the display device based on context of use thereof, said drive device comprising:
a repository configured to store information related to profiles of the user, said repository further configured to store information corresponding to operating systems previously executed by the user, said repository still further configured to store instances of operating system previously executed by the user, said repository still further configured to store information corresponding to the access rights assigned to each of the profiles of the user, said repository still further configured to store information corresponding to the authentication mechanism previously used by the user to authenticate himself;
a processor configured to determine current location and hardware characteristics of the display device, said processor further configured to determine current time of the day, said processor further configured to analyze the information stored in said repository and determine at least the profile, instance of operating system, access rights and authentication mechanism corresponding to the context of use of the display device;
said drive device configured to modify the behavior of display device by loading onto the display device the instance of operating system relevant to the location and time of the day of the display device, said drive device further configured to modify the behavior of display device by loading onto the display device the profile relevant to the location and time of the day of the display device.

2. The drive device as claimed in claim 1, wherein said drive device is further configured to modify the behavior of display device, by loading onto the display device the instance of operating system relevant to the authentication mechanism utilized by the user.

3. The drive device as claimed in claim 1, wherein said drive device is further configured to modify the behavior of display device, by loading onto the display device the profile relevant to the authentication mechanism utilized by the user.

4. The drive device as claimed in claim 1, wherein said drive device is further configured to determine the size of the display device coupled thereto, said drive device configured to load onto the display device, the profile and instance of operating system relevant to the authentication mechanism utilized by the user.

5. The drive device as claimed in claim 1, wherein said drive device is further configured to determine the network access points connected to the display device, said drive device configured to load onto the display device, the profile and instance of operating system based on the network access point connected to the display device.

6. A method for selectively modifying the behavior of display device based on context of use thereof, said method comprising the following steps:
communicably coupling the display device with a drive device;
storing information related to profiles of the user, in a repository of the drive device;
storing information corresponding to operating systems previously executed by the user;
storing instances of operating system previously executed by the user, in said repository;
storing, in said repository, information corresponding to the access rights assigned to each of the profiles of the user, and storing information corresponding to the authentication mechanism previously used by the user to authenticate himself;
determining current location and hardware characteristics of the display device, using a processor;
determining current time of the day, using said processor;
analyzing the information stored in said repository using said processor and determining at least the profile, instance of operating system, access rights and authentication mechanism corresponding to the context of use of the display device;
modifying the behavior of display device by loading onto the display device the instance of operating system relevant to the location and time of the day of the display device; and
modifying the behavior of display device, by loading onto the display device the profile relevant to the location and time of the day of the display device.

7. The method as claimed in claim 6, wherein the step of modifying the behavior of display device, further includes the step of modifying the behavior of the display device by loading onto the display device the instance of operating system relevant to the authentication mechanism utilized by the user.

8. The method as claimed in claim 6, wherein the step of modifying the behavior of display device, further includes the step of modifying the behavior of display device, by loading onto the display device the profile relevant to the authentication mechanism utilized by the user.

9. The method as claimed in claim 6, wherein the step of modifying the behavior of display device, further includes the step of modifying the behavior of display device, by loading onto the display device, the profile and instance of operating system relevant to the authentication mechanism utilized by the user.

10. The method as claimed in claim 6, wherein the step of modifying the behavior of display device, further includes the step of modifying the behavior of display device, the profile and instance of operating system based on the network access point connected to the display device.
